(19) United States
(12) Patent Application Publication
(10) Pub. No.: US 2011/0168247 A1
(43) Pub. Date: Jul. 14, 2011

(54) Techniques for Cooling Solar Concentrator Devices

(75) Inventors: Supratik Guha, Chappaqua, NY (US); Theodore Gerard van Kessel, Millbrook, NY (US); Yves C. Martin, Ossining, NY (US)

(73) Assignee: International Business Machines Corporation, Armonk, NY (US)

(21) Appl. No.: 13/069,403

(22) Filed: Mar. 23, 2011

Related U.S. Application Data
(63) Continuation of application No. 11/865,121, filed on Oct. 1, 2007.

(51) Int. Cl. H01L 31/024; H01L 31/06; H01L 31/18

(52) U.S. Cl. 136/255; 136/259; 438/64; 257/E31.131

(57) ABSTRACT

Solar concentrator devices and techniques for the fabrication thereof are provided. In one aspect, a solar concentrator device is provided. The solar concentrator device comprises at least one solar converter cell; a heat sink; and a liquid metal between the solar converter cell and the heat sink, configured to thermally couple the solar converter cell and the heat sink during operation of the device. The solar converter cell can comprise a triple junction semiconductor solar converter cell fabricated on a germanium (Ge) substrate. The heat sink can comprise a vapor chamber heat sink. The liquid metal can comprise a gallium (Ga) alloy and have a thermal resistance of less than or equal to about five square millimeter degree Celsius per Watt (mm²° C./W).

CROSS-REFERENCE TO RELATED APPLICATION(S)

This application is a continuation of U.S. application Ser. No. 11/865,121 filed on Oct. 1, 2007, the disclosure of which is incorporated by reference herein.

### FIELD OF THE INVENTION

The present invention relates to solar concentrator devices, and more particularly, to techniques for cooling solar concentrator devices.

### BACKGROUND OF THE INVENTION

Increasing energy costs make solar power an attractive alternative to traditional energy sources. One method for converting sunlight into usable electricity is through the use of solar concentrator devices which typically employ mirrors or lenses to concentrate the sunlight onto solar converter cells. The solar cells then convert the sunlight energy into electricity.

Solar concentrator devices are advantageous, as they employ a fewer number of solar converter cells as compared to full panel solar devices. A fewer number of solar converter cells, however, means that for a given output each solar converter cell has to accommodate a higher incident solar power level. For the solar concentrator devices to be practical for widespread implementation, it is also desirable that these devices operate at a high efficiency (conversion efficiency of light energy into electricity).

As improvements in solar device technology occur, it is expected that incident power level capacities will continue to increase, as will efficiency requirements. One factor, however, that limits the power level capacity of solar concentrator devices is heat management. Namely, solar cells operate within a certain temperature range. For example, semiconductor solar cells are typically restricted to operations at a temperature of about 85 degrees Celsius (° C.) under ambient air temperatures of 35° C., or higher. Higher incident solar power levels result in larger amounts of waste heat that have to be removed to prevent overheating of the solar converter cells.

Cost is a factor in many applications where solar concentrator devices are used. Therefore, less expensive cooling techniques, such as passive cooling, are an attractive option. Namely, in some solar concentrator device configurations, a vapor chamber heat sink is coupled to the solar converter cell and serves to dissipate heat to the ambient air during operation.

The interface between the solar converter cell and the heat sink, however, can limit the amount of heat that is transferred from the solar converter cell to the heat sink. For example, since vapor chamber heat sinks generally cannot withstand the temperatures that would be needed to solder attach them directly to the solar converter cells, thermal interface materials (TIMs) are commonly used to thermally couple the solar converter cell with the heat sink. Common TIMs however do not permit the necessary heat transfer to maintain the solar converter cells at acceptable operating temperatures when incident solar power levels are greater than or equal to about 100 Watts per square centimeter (W/cm²).

Therefore, improved techniques for cooling solar converter cells, so as to increase the power level capacity of solar concentrator devices, would be desirable.

### SUMMARY OF THE INVENTION

The present invention provides solar concentrator devices and techniques for the fabrication thereof. In one aspect of the invention, a solar concentrator device is provided. The solar concentrator device comprises at least one solar converter cell; a heat sink; and a liquid metal between the solar converter cell and the heat sink, configured to thermally couple the solar converter cell and the heat sink during operation of the device. The solar converter cell can comprise a triple junction semiconductor solar converter cell fabricated on a germanium (Ge) substrate. The heat sink can comprise a vapor chamber heat sink. The liquid metal can comprise a gallium (Ga) alloy and have a thermal resistance of less than or equal to about five square millimeter degree Celsius per Watt (mm²° C./W).

In another aspect of the invention, a method of fabricating a solar concentrator device is provided. The method comprises the following steps. At least one solar converter cell is provided. A heat sink is provided. A liquid metal is placed between the solar converter cell and the heat sink. The liquid metal is configured to thermally couple the solar converter cell and the heat sink during operation of the device.

A more complete understanding of the present invention, as well as further features and advantages of the present invention, will be obtained by reference to the following detailed description and drawings.

### BRIEF DESCRIPTION OF THE DRAWINGS

FIG. 1 is a diagram illustrating a cross-sectional view of an exemplary solar concentrator device according to an embodiment of the present invention;

FIG. 2 is a diagram illustrating a cross-sectional view of another exemplary solar concentrator device according to an embodiment of the present invention;

FIG. 3 is a diagram illustrating a cross-sectional view of an exemplary triple-junction semiconductor solar converter cell according to an embodiment of the present invention;

FIG. 4 is a diagram illustrating a cross-sectional view of an exemplary vapor chamber heat sink according to an embodiment of the present invention;

FIG. 5 is a diagram illustrating an exemplary methodology for fabricating a solar concentrator device according to an embodiment of the present invention; and

FIG. 6 is a graph illustrating thermal performance of liquid metal according to an embodiment of the present invention.

### DETAILED DESCRIPTION OF PREFERRED EMBODIMENTS

FIG. 1 is a diagram illustrating a cross-sectional view of exemplary solar concentrator device 100. Solar concentrator device 100 comprises solar converter cell 102, heat sink 104 and liquid metal 106 between solar converter cell 102 and heat sink 104. As will be described in detail below, liquid metal 106 is configured to serve as a thermal interface between solar converter cell 102 and heat sink 104 (i.e., to thermally couple solar converter cell 102 to heat sink 104) during operation of solar concentrator device 100.

For ease of depiction, FIG. 1 illustrates a solar concentrator device having a single solar converter cell. It is to be understood, however, that multiple solar converter cells may be coupled to a common heat sink. In some instances, having multiple solar converter cells coupled to a common heat sink is preferred, as this configuration results in a reduction in number of parts, costs and production time. Further, the liquid metal thermal interface described herein enables multiple solar converter cells to be coupled to a common heat sink, e.g., by permitting motion due to thermal expansion to occur freely between the solar converter cells and the heat sink (see below).

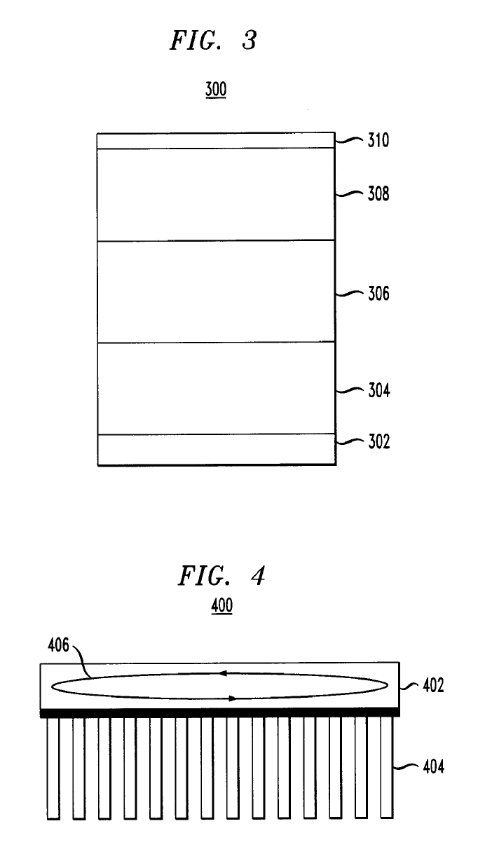

According to an exemplary embodiment, solar converter cell 102 is a multi-junction semiconductor solar converter cell. By way of example only, solar converter cell 102 can be a triple junction semiconductor solar converter cell fabricated on a flat germanium (Ge) substrate. An exemplary triple junction semiconductor solar converter cell is shown in FIG. 3 (described below). According to the present techniques, solar converter cell 102 has an efficiency (conversion efficiency of light energy into electricity) of greater than about 20 percent (%) with an incident solar power level of about 400 suns (i.e., 40 Watts per square centimeter (W/cm²)).

Heat sink 104 can comprises a fin assembly (not shown) joined to either a metal base or a vapor chamber. In the instance where heat sink 104 comprises a vapor chamber, heat sink 104 is referred to herein as a vapor chamber heat sink. An exemplary vapor chamber heat sink is shown in FIG. 4 (described below). Further, heat sink 104 can comprise one or more heat pipes (not shown) that serve to cool the solar converter cell via evaporation/condensation of a fluid(s) contained therein.

In conventional solar concentrator devices, a thermal grease, an adhesives, a gel material, a paste and/or a thermally conductive metal or oxide in an organic matrix (collectively referred to herein as “thermal interface materials” or “TIMs”) are placed between a solar converter cell and a heat sink. However, the thermal resistance of these conventional TIMs is about 15 square millimeter degree Celsius per Watt (mm²° C./W).

Therefore, in a case where a solar converter cell is operated at 1,000 suns (i.e., 100 W/cm2) of incident power, 15 degree Celsius (° C.) is measured across the interface of the solar converter cell and the heat sink. If it is desired to operate the solar converter cell at 85° C. (a typical value for a semiconductor solar converter cell), the 15° C. drop, i.e., thermal resistance, represents a loss of 30% of the total thermal budget across the interface. This thermal resistance has an effect equivalent to raising ambient temperatures, thus making cooling more difficult.

According to the present teachings, a liquid metal, i.e., liquid metal 106, is present between the solar converter cell and the heat sink, and forms a thermal interface between the solar converter cell and the heat sink. The term “thermal interface,” as used herein, refers generally to any interface between the solar converter cell and the heat sink through which heat energy can be transferred.

According to an exemplary embodiment, the liquid metal comprises a gallium (Ga) alloy, such as a Ga-indium (In)-tin (Sn) eutectic alloy. Suitable Ga alloys for use in the present techniques include, but are not limited to, Ga alloys which have melting points between about 10.5° C. and about 15° C. Thus, in general, the metal remains a liquid (i.e., in a liquid state) at temperatures above about 15° C., which includes normal operating temperatures that are generally less than or equal to about 85° C. The Ga alloy may, in some instances, additionally comprise one or more of In (as in the example above), bismuth (Bi), antimony (Sb), Sn (as in the example above) and lead (Pb). Variations in the alloy composition affect, e.g., the melting point and/or corrosion properties of the alloy. The thermal performance of liquid metal, i.e., versus conventional pastes, is described in conjunction with the description of FIG. 6, below.

According to the present teachings, liquid metal 106 has a thermal resistance of less than or equal to about five mm²° C./W. For example, a liquid metal comprising a Ga—In—Sn eutectic alloy has a thermal resistance of about two mm²° C./W. Thus, in the example provided above wherein the solar converter cell is operated at 100 W/cm² of incident power, the use of a liquid metal comprising a Ga—In—Sn eutectic alloy reduces the 15° C. drop for conventional TIMs to two ° C.

The use of a liquid metal as the thermal interface provides several notable benefits. First, as highlighted above, a liquid metal provides a significantly higher efficiency thermal interface as compared to conventional TIMs. Therefore, higher power level operations can be supported using a liquid metal as the thermal interface without having to switch to more expensive cooling techniques.

Second, in addition to being thermally conductive, a liquid metal is also electrically conductive. Therefore, in some embodiments, the liquid metal can further serve as an electrical conduit to the solar converter cell. This benefit is important at high power levels, for example, when it is necessary to conduct 20 amps or more of current (referred to herein as “photocurrent”) from the solar converter cell. According to an exemplary embodiment, the solar converter cell comprises two electrodes. One electrode comprises an underside of the solar converter cell (i.e., a side of the solar converter cell facing the heat sink). The other electrode is formed as a grid on a top surface of the solar converter cell (i.e., on a side of the solar converter cell opposite the heat sink). Thus, when the liquid metal serves as an electrical conduit to the solar converter cell, the photocurrent passes from the solar converter cell, through the liquid metal, to the heat sink (from which it is conducted, e.g., using wire to a load).

Third, use of some of the conventional TIMs require additional time consuming processing steps. For example, conventional thermal interface adhesive materials (highlighted above) generally require a curing cycle. The use of a liquid metal does not involve any such time consuming processing steps.

Fourth, the solar converter cell is clamped to the heat sink, i.e., by retainer 108, so as to trap a portion of the liquid metal therebetween. A liquid metal is very easy to evenly distribute between the solar converter cell and the heat sink with minimal clamping pressure. In contrast, a conventional thermal grease (as highlighted above) has a higher viscosity than the liquid metal and therefore would require a proportionally greater amount of clamping pressure to be properly spread over the surfaces of the solar converter cell and the heat sink. Since solar converter cells are typically less than about one millimeter (mm) thick, and have less structural support than conventional semiconductor chips (e.g., microprocessors), solar converter cells can easily be damaged, through fracture, by excessive mechanical stress.

Fifth, a liquid metal thermal interface allows the solar converter cell and the heat sink to expand and contract independently of one another, and to slide relative to one another during use. This property is important, as solar concentrator devices undergo significant thermal cycling.

Sixth, a liquid metal thermal interface allows the solar concentrator device to be easily disassembled/reworked and re-assembled, as needed, e.g., in the field. In contrast, many conventional TIMs, such as thermal interface adhesive materials (highlighted above), generate a permanent or semi-permanent bond that cannot easily be reworked.

In use, solar concentrator devices experience prolonged exposure to a wide variety of harsh climate conditions, such as ultraviolet radiation and extreme temperature and humidity. Corrosives, such as salt spray and atmospheric pollution, are also present in some environments. Despite these conditions, solar concentrator devices are generally expected to have lifetimes of between about 10 years and about 20 years.

To insure that the liquid metal can withstand these conditions, several components are provided to protect the liquid metal from environmental factors. As shown in FIG. 1, liquid metal 106 (represented with a dotted pattern) is retained at the thermal interface between solar converter cell 102 and heat sink 104 (as well as under a portion of retainer 108) by gasket assembly 110 present between retainer 108 and heat sink 104 and surrounding solar converter cell 102.

As shown in magnified view 100a of gasket assembly 110, gasket assembly 110 comprises a gasket 112 and a lubricant seal 114. Gasket 112 is hermetic and comprises, for example, a metal or a metal-coated plastic hermetic gasket. According to an exemplary embodiment, gasket 112 comprises an electroformed metal hermetic gasket. An electroformed metal hermetic gasket is beneficial as it permits tight design tolerances and thus provides a proper seal between retainer 108 and heat sink 104. Preferred lubricants for forming lubricant seal 114, include, but are not limited to, lubricants having a low water vapor transport rate, such as perfluoropolyethers. As such, gasket 112 and lubricant seal 114 serve to contain the liquid metal at the thermal interface.

Desiccant insert 116 is also present between retainer 108 and heat sink 104 and surrounding solar converter cell 102. According to an exemplary embodiment, desiccant insert 116 comprises one or more of a desiccating material, such as silica gel, a molecular sieve and a desiccating material dispersed in a polymer matrix. A suitable polymer matrix includes, but is not limited to, silicone rubber. FIG. 1 is a cross-sectional representation of the solar concentrator device. Thus, it is to be understood that retainer 108, gasket assembly 110 and desiccant insert 116 are, in the embodiment shown in FIG. 1, continuous around one or more sides of solar converter cell 102.

In addition to retaining the liquid metal at the thermal interface, gasket assembly 110 along with desiccant insert 116 are employed to isolate the liquid metal from moisture and corrosive chemicals, as well as from other elements of the system (e.g., fluxes or outgassing materials from the device package). It is notable that, while preferable, it is however not necessary for the desiccant insert to be continuous around the solar converter cell to protect the liquid metal from moisture. In the case where the desiccant insert is continuous around, i.e., surrounds, the solar converter cell, the desiccant insert can be constructed to serve the additional role of confining the liquid metal to the interface between the solar converter cell and the heat sink. In this instance, the desiccant insert serves as an additional gasket, which is desirable if significant shock loads are expected.

According to an exemplary embodiment, those surfaces of the heat sink and the solar converter cell that are in contact with the liquid metal are coated with an adherence layer in combination with a wetting layer. Namely, the adherence layer serves to adhere the wetting layer to the base material, i.e., of the solar converter cell and/or the heat sink. The wetting layer provides a wetting surface for the liquid metal. Further, the adherence/wetting layers serve to isolate the liquid metal from the heat sink material. For example, if the heat sink comprises aluminum (Al) and/or Copper (Cu) (as will be described in detail below) and if the liquid metal comprises Ga (as described above), without the adherence/wetting layers an undesirable interaction between the Al/Cu and the Ga can occur.

According to an exemplary embodiment, the adherence layer comprises one or more of titanium (Ti), chromium (Cr), stainless steel, tantalum (Ta), tungsten (W), molybdenum (Mo), nickel (Ni), vanadium (V), and the wetting layer comprises one or more of gold (Au) and platinum (Pt). For example, the surfaces of the heat sink and the solar converter cell that are in contact with the liquid metal can be covered with a Au layer over a Ti layer. When depositing the layers, the Au layer should be deposited immediately after the Ti layer is deposited to prevent oxidation of the Ti layer. Surface oxide is to be avoided, as only an oxide-free surface allows for proper wetting of the liquid metal.

Solar concentrator device 100 may further comprise one or more mirrors and/or lenses (not shown) to focus the sunlight onto solar converter cell 102. Accordingly, incident power levels of up to about 2,000 suns (i.e., 200 W/cm²) can be expected in the field. In laboratory tests, incident power levels in excess of 200 W/cm² have been demonstrated.

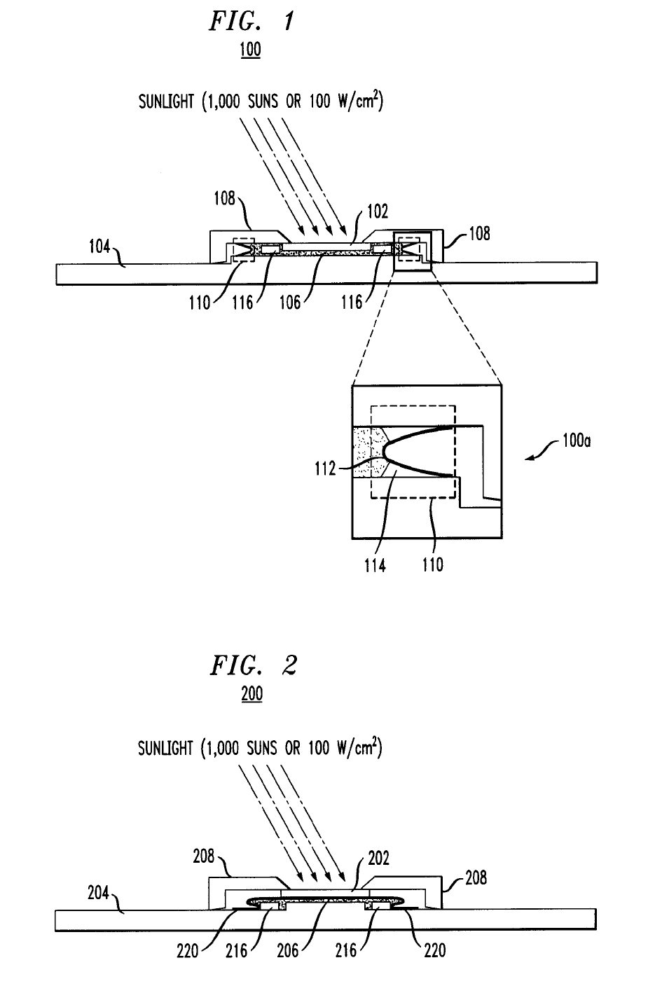

FIG. 2 is a diagram illustrating a cross-sectional view of exemplary solar concentrator device 200. Solar concentrator device 200 comprises solar converter cell 202 attached to interposer gasket 220 (e.g., using solder), heat sink 204 and liquid metal 206 between interposer gasket 220 and heat sink 204. Liquid metal 206 is configured to serve as a thermal interface between interposer gasket 220 and heat sink 204 (i.e., to thermally couple solar converter cell 202 to heat sink 204) during operation of solar concentrator device 200.

For ease of depiction, FIG. 2 illustrates a solar concentrator device having a single solar converter cell. It is to be understood, however, that multiple solar converter cells may be coupled to a common heat sink.

According to an exemplary embodiment, solar converter cell 202 is a multi-junction semiconductor solar converter cell. By way of example only, solar converter cell 202 can be a triple junction semiconductor solar converter cell fabricated on a flat Ge substrate. An exemplary triple junction semiconductor solar converter cell is shown in FIG. 3 (described below). According to the present techniques, solar converter cell 202 has an efficiency (conversion efficiency of light energy into electricity) of greater than about 20% with an incident solar power level of about 400 suns (i.e., 40 W/cm²).

Heat sink 204 can comprises a fin assembly (not shown) joined to either a metal base or a vapor chamber. In the instance where heat sink 204 comprises a vapor chamber, heat sink 204 is referred to herein as a vapor chamber heat sink. An exemplary vapor chamber heat sink is shown in FIG. 4 (described below). Further, heat sink 204 can comprise one or more heat pipes (not shown) that serve to cool the solar converter cell via evaporation/condensation of a fluid(s) contained therein.

According to an exemplary embodiment, liquid metal 206 comprises a Ga alloy, such as a Ga—In—Sn eutectic alloy. Suitable Ga alloys for use in the present techniques, include, but are not limited to, Ga alloys which have melting points between about 10.5° C. and about 15° C. Thus, in general, the metal remains a liquid (i.e., in a liquid state) at temperatures above about 15° C., which includes normal operating temperatures that are generally less than or equal to about 85° C. The Ga alloy may, in some instances, additionally comprise one or more of In (as in the example above), Bi, Sb, Sn (as in the example above) and Pb. Variations in the alloy composition affect, e.g., the melting point and/or corrosion properties of the alloy. The thermal performance of liquid metal, i.e., versus conventional pastes, is described in conjunction with the description of FIG. 6, below. According to the present teachings, liquid metal 206 has a thermal resistance of less than or equal to about five mm²° C./W.

Solar converter cell 202 is attached to interposer gasket 220. As shown in FIG. 2, interposer gasket 220 can be configured to have a flat center (to provide an attachment surface for solar converter cell 202) and curved edges (to form a seal against heat sink 204, thereby containing the liquid metal at the interface between interposer gasket 220 and heat sink 204). According to an exemplary embodiment, interposer gasket 220 comprises a thin metal gasket and solar converter cell 202 is solder attached to interposer gasket 220. Interposer gasket 220 can comprise any metal that can be made into a sheet form, such as Ni, stainless steel, iron (Fe), Cu and Al. According to an exemplary embodiment, interposer gasket comprises Ni. Further, interposer gasket 220 can have a thickness of about 0.05 mm.

As shown in FIG. 2, liquid metal 206 (represented by a dotted pattern) is retained at the thermal interface between interposer gasket 220 and heat sink 204 by interposer gasket 220. It is notable that, in this embodiment, interposer gasket 220 is integral to thermally coupling solar converter cell 202 and heat sink 204.

According to an exemplary embodiment, those surfaces of the heat sink and the interposer gasket that are in contact with the liquid metal are coated with an adherence layer in combination with a wetting layer. Namely, the adherence layer serves to adhere the wetting layer to the base material, i.e., of the interposer gasket and/or the heat sink. The wetting layer provides a wetting surface for the liquid metal. Further, the adherence/wetting layers serve to isolate the liquid metal from the interposer gasket/heat sink material. For example, if the heat sink comprises Al and/or Cu (as will be described in detail below) and if the liquid metal comprises Ga (as described above), without the adherence/wetting layers an undesirable interaction between the Al/Cu and the Ga can occur.

According to an exemplary embodiment, the adherence layer comprises one or more of Ti, Cr, stainless steel, Ta, W, Mo, Ni, V, and the wetting layer comprises one or more of Au and Pt. For example, the surfaces of the heat sink and the interposer gasket that are in contact with the liquid metal can be covered with a Au layer over a Ti layer. When depositing the layers, the Au layer should be deposited immediately after the Ti layer is deposited to prevent oxidation of the Ti layer. Surface oxide is to be avoided, as only an oxide-free surface allows for proper wetting of the liquid metal.

Desiccant insert 216 is present between interposer gasket 220 and heat sink 204 and serves to isolate the liquid metal from moisture and corrosive chemicals, as well as from other elements of the system. According to an exemplary embodiment, desiccant insert 216 comprises one or more of a desiccating material, such as silica gel, a molecular sieve and a desiccating material dispersed in a polymer matrix. A suitable polymer matrix includes, but in not limited to, silicone rubber. FIG. 2 is a cross-sectional representation of the solar concentrator device. Thus, it is to be understood that retainer 208, interposer gasket 220 and desiccant insert 216 are, in the embodiment shown in FIG. 2, continuous structures. It is notable that, while preferable, it is however not necessary for the desiccant insert to be continuous to protect the liquid metal from moisture. In the case where the desiccant insert is continuous, the desiccant insert can be constructed to serve the additional role of confining the liquid metal to the interface between the interposer gasket and the heat sink. In this instance, the desiccant insert serves as an additional gasket, which is desirable if significant shock loads are expected.

Solar concentrator device 200 may further comprise one or more mirrors and/or lenses (not shown) to focus the sunlight onto solar converter cell 202. Accordingly, incident power levels of up to about 2,000 suns (i.e., 200 W/cm²) can be expected in the field. In laboratory tests, incident power levels in excess of 200 W/cm² have been demonstrated.

FIG. 3 is a diagram illustrating a cross-sectional view of exemplary triple-junction semiconductor solar converter cell 300. Triple junction semiconductor solar converter cell 300 represents one possible configuration of solar converter cell 102 and/or solar converter cell 202, described in conjunction with the description of FIG. 1 and FIG. 2, respectively, above. Triple junction semiconductor solar converter cell 300 comprises substrate 302, solar cells 304, 306 and 308 and anti-reflective coating 310. According to an exemplary embodiment, substrate 302 comprises a Ge substrate and has a thickness of about 200 micrometers (μm). As highlighted above, a solar converter cell, such as triple-junction semiconductor solar converter cell 300, can have an overall thickness of less than about one mm.

Solar cell 304 may be separated from solar cell 306 by a tunnel diode (not shown). Similarly, solar cell 306 may be separated from solar cell 308 by a tunnel diode (not shown). Each of solar cells 304, 306 and 308 should be configured such that, collectively, solar cells 304, 306 and 308 absorb as much of the solar spectrum as possible. By way of example only, solar cell 304 can comprise Ge, solar cell 306 can comprise gallium arsenide (GaAs) and solar cell 308 can comprise gallium indium phosphide (GaInP).

FIG. 4 is a diagram illustrating a cross-sectional view of exemplary vapor chamber heat sink 400. Vapor chamber heat sink 400 represents one possible configuration of heat sink 104 and/or heat sink 204, described in conjunction with the description of FIG. 1 and FIG. 2, respectively, above. Vapor chamber heat sink 400 comprises vapor chamber 402 and fin assembly 404 attached to vapor chamber 402. A vapor chamber permits more efficient heat transfer, e.g., as compared to a solid metal block. Namely, as indicated by arrows 406, the vapor chamber permits convective heat transfer to the fin assembly.

According to one exemplary embodiment, both the vapor chamber 402 and fin assembly 404 comprise Al and/or Cu. The fin assembly may also include heat pipes (not shown) to spread the heat load more efficiently.

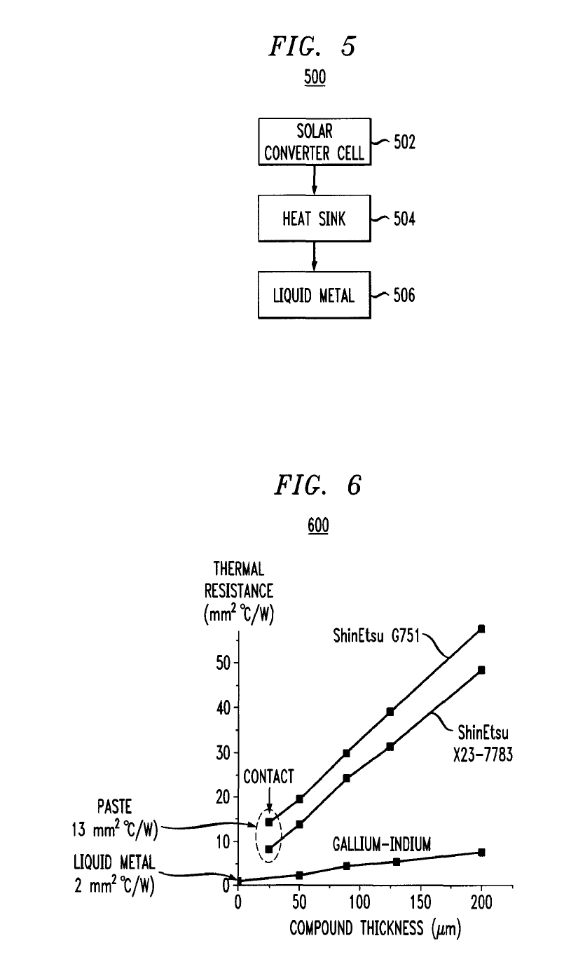

FIG. 5 is a diagram illustrating exemplary methodology 500 for fabricating a solar concentrator device. In step 502, at least one solar converter cell is provided. The solar converter cell can comprise a triple junction semiconductor solar converter cell (as described above). In step 504, a heat sink is provided. The heat sink can comprise a vapor chamber heat sink (as described above). In step 506, a liquid metal is placed between the solar converter cell and the heat sink and is used to form a thermal interface between the solar converter cell and the heat sink during operation of the device. According to an exemplary embodiment, the liquid metal comprises a Ga—In—Sn alloy (as described above).

FIG. 6 is a graph 600 illustrating thermal performance of liquid metal versus conventional pastes. Specifically, graph 600 compares a liquid metal comprising a Ga—In alloy with a couple of conventional pastes, i.e., Shin-Etsu G751 and Shin-Etsu X23-7783 (manufactured by the Shin-Etsu Chemical Co., Ltd., Tokyo, Japan). When compared at a thickness of about 25 μm, the liquid metal exhibits a lower thermal resistance (i.e., two mm²° C./W) than each of the conventional pastes (i.e., having an average thermal resistance of about 13 mm²° C./W).

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A solar concentrator device comprising:
at least one solar converter cell;
a heat sink;
a liquid metal between the solar converter cell and the heat sink for thermally coupling the solar converter cell and the heat sink during operation of the device; and
a metal interposer gasket solder attached to the solar converter cell for retaining the liquid metal between the interposer gasket and the heat sink.

2. The device of claim 1, wherein the solar converter cell comprises a triple junction semiconductor solar converter cell fabricated on a germanium substrate.

3. The device of claim 1, wherein the solar converter cell is a triple junction semiconductor solar converter cell comprising:
a substrate;
a first solar cell over the substrate, the first solar cell comprising germanium;
a second solar cell over the first solar cell, the second solar cell comprising gallium arsenide; and
a third solar cell over the second solar cell, the third solar cell comprising gallium indium phosphide.

4. The device of claim 1, wherein the heat sink comprises a vapor chamber heat sink.

5. The device of claim 1, wherein the heat sink further comprises a fin assembly attached thereto.

6. The device of claim 1, wherein the liquid metal comprises a gallium alloy.

7. The device of claim 1, wherein the liquid metal comprises a gallium alloy having a melting point between about 10.5° C. and about 15° C.

8. The device of claim 1, wherein the liquid metal comprises an alloy of gallium with one or more of indium, bismuth, antimony, tin and lead.

9. The device of claim 1, wherein the liquid metal has a thermal resistance of less than or equal to about five mm²° C./W.

10. The device of claim 1, wherein one or more surfaces of the interposer gasket in contact with the liquid metal comprise an adherence layer thereon, and a wetting layer over the adherence layer.

11. The device of claim 10, wherein the adherence layer comprises one or more of titanium, chromium, stainless steel, tantalum, tungsten, molybdenum, nickel and vanadium.

12. The device of claim 10, wherein the wetting layer comprises one or more of gold and platinum.

13. The device of claim 1, further comprising a desiccant insert between the interposer gasket and the heat sink, configured to isolate the liquid metal from moisture.

14. The device of claim 13, wherein the desiccant insert comprises one or more of a desiccating material, silica gel, a molecular sieve and a desiccating material dispersed in a polymer matrix.

15. A method of fabricating a solar concentrator device, the method comprising the steps of:
providing at least one solar converter cell;
providing a heat sink;
placing a liquid metal between the solar converter cell and the heat sink for thermally coupling the solar converter cell and the heat sink during operation of the device; and
solder attaching a metal interposer gasket to the solar converter cell for retaining the liquid metal between the interposer gasket and the heat sink.
